(19) United States
(12) Patent Application Publication
(10) Pub. No.: US 2017/0355877 A1
(43) Pub. Date: Dec. 14, 2017

(54) CURABLE ORGANOPOLYSILOXANE COMPOSITION AND ITS APPLICATION

(71) Applicants: Ning-Kang SUNG, Dongguan City (CN); Pei-Yu LIN, Taipei City (TW); Chih-Fu KANG, Taipei City (TW)

(72) Inventors: Ning-Kang SUNG, Dongguan City (CN); Pei-Yu LIN, Taipei City (TW); Chih-Fu KANG, Taipei City (TW)

(73) Assignee: Dongguan Tiankai Electronic Co. Ltd., Dongguan City (CN)

(21) Appl. No.: 15/178,207

(22) Filed: Jun. 9, 2016

(51) Int. Cl. C09D 183/04; H01L 33/56; C09D 5/08

(52) U.S. Cl. CPC C09D 183/04; C09D 5/084; H01L 33/56

(57) ABSTRACT

The present invention provides a curable organopolysiloxane composition comprising one or more from a group including magnesium oxide, magnesium hydroxide, magnesium carbonate, hydrotalcite, hydrotalcite-like compounds, and magnesium silicate. The application of said organopolysiloxane composition in semiconductor devices of light emitting components may effectively block the permeation of hydrogen sulfide or sulfide and prevent silver-plated laminates from being oxidated without affecting the original light output efficiency, so that silver-plated laminates may be effectively protected and anti-sulfidation effect may be enhanced.

### BACKGROUND OF THE INVENTION

### 1. Field of the Invention

The present invention relates to a curable organopolysiloxane composition and its application in semiconductor devices of light emitting components.

### 2. Description of Related Art

A phenyl-alkyl-alkenyl-containing and silica bonded (including stretch bonded and branch bonded) organopolysiloxane compound is transformed into a curable organopolysiloxane composition after hydrogenated silane reaction with organoplatinum as a catalyst, enyne compound as a work time conditioning agent, and appropriate amount of proper fluorescent powder as a light effect conditioning agent. This curable organopolysiloxane composition is widely applied in the manufacture of a protective sealing layer of LED (light-emitting diode), forming a light transmittant resin body with a refractive index between 1.40 and 1.57. Opto-electronic coupled LED emits electricity from a chip in the form of light. Various kinds of opto-electronic components are formed with the use of electrodeless fluorescent powder and applied in the display and illumination industry. Silver-plated laminate substrates at the bottoms of the opto-electronic components reflect light to achieve a certain amount of opto-electronic effect.

However, the foregoing type of organopolysiloxane structure has certain gaseous permeability regardless of its refractive index and hardness. In natural environment, or in electronic, appliance, device compositions, there always exists a certain amount of hydrogen sulfide or sulfide. The sulfide would usually permeate the organopolysiloxane coating in normal or high temperature, culminates on the silver-plated laminate substrate at the bottom, and forms into dark silver sulfide. Gradually, the LED component would become unable to reflect light, causing lumen depreciation. This problem has been bothering LED encapsulators, who have been seeking better solutions.

### SUMMARY OF THE INVENTION

It is a primary purpose of the present invention to provide a curable organopolysiloxane composition which may effectively block the permeation of hydrogen sulfide or sulfide and prevent silver-plated laminates from being oxidated without affecting the original light output efficiency, so that silver-plated laminates may be effectively protected and anti-sulfidation effect may be enhanced.

To achieve the foregoing purpose, the present invention provides:

a curable organopolysiloxane composition, characterized in that: the said composition also includes 0.1-50 wt % of nonorganic magnesium compounds, with a particle size of 0.01-50 um;

a curable organopolysiloxane composition, the said nonorganic magnesium compounds is one or more from a group including magnesium oxide, magnesium hydroxide, magnesium carbonate, hydrotalcite, hydrotalcite-like compounds, and magnesium silicate;

the content of said nonorganic magnesium compounds is 0.1-20 wt %, preferably 3-10 wt %, and the particle size is 0.01-20 um, preferably 0.1-20 um;

It is another primary purpose of the present invention to provide a method of applying the said curable organopolysiloxane composition in semiconductor devices of light emitting components.

Further, without impairing the primary purposes of the present invention, as alternative components, the present invention may also include proper heat stabilizer, pigments, adhesion promoter, and anti-settling agent, etc.

The present invention may achieve the following technical effects:

1. Organopolysiloxane composition containing no magnesium compounds serves as the control group, and organopolysiloxane compositions containing respectively 3%, 5%, and 10% of magnesium hydroxide are experimental groups. They are respectively encapsulated on LED components, placed in an enclosed container with sulfur powder and water, and stored at the temperature of 85° C. After seven hours, the light output ratio of the component with organopolysiloxane composition containing no magnesium hydroxide is reduced by nearly 29%, from 28 to 20 Lumen. By contrast, the light output ratios of the components with organopolysiloxane composition containing 3%, 5%, and 10% of magnesium hydroxide are respectively reduced by only 2.5%, 0.7%, and 0%, from 28 to 27.3, 27.8, and 28 Lumen respectively.

2. The present invention creatively includes preferred contents of nonorganic magnesium compounds of preferred particle sizes in organopolysiloxane composition. It may effectively block the permeation of hydrogen sulfide or sulfide and prevent silver-plated laminates from being oxidated without affecting the original light output radio. The present invention achieves the effect of effectively protecting silver-plated laminates and enhancing anti-sulfidation effect. With the addition of nonorganic magnesium compounds, brightness decay is kept under 2%. Further, such preferred nonorganic magnesium compounds may also achieve the unexpected technical effect of preventing fluorescent powder from settling during the curing process.

### DETAILED DESCRIPTION OF THE PREFERRED EMBODIMENTS

### Implementation Procedures and Conditions:

1. High-temperature and high-humidity reflow soldering: Place the lamp beads in a container at 85° C. and 85% RH for 24 hours. Take out the lamp beads and wipe them dry before placing them into a reflow soldering tunnel at 265° C. for 5 minutes for two rounds.

2. High-temperature ageing: Place the lamp beads in a hot air circulation drying oven at 200° C. for 72 hours.

3. Temperature cycling: −40° C. to 100° C. single-tanked thermocycler, 20 cycles per day, 10 days in all.

4. Sulfidation: Fill 10 g of sulfur powder and 300 cc of mineral water at a bottom of a 20-litre enclosed container (diameter=30 cm; height=30 cm). Attach the chips of lamp beads to be tested face down inside a top end of the container. Place the lamp beads in a circulation thermostatic drying oven at 80° C. for 8 hours. Then take them out and clean up the corrosion on the silver lead of the mount. Then inspect their brightness (Lv) and color temperature on an inspection machine specifically for lamp beads.

5. Bare die permeability: The permeability rate (%) with the spectrophotometer set at 420 nm (light path=l0 mm).

6. Hardness: Measured according to ASTM D 2240 D.

### Embodiment 1

Evenly mix polymethylphenylsiloxane polymer containing silica bonded vinyl group with polymethylphenylsiloxane polymer containing silica bonded hydrogen, wherein the content of silica bonded vinyl group is 4.5 wt %, the content of silica bonded hydrogen is 0.13 wt %, and the content of silica bonded phenyl group is 49 wt %. Platinum-1,3-divenyl-1,1,3,3-tetramethyldisiloxane complex serves as a catalyst (with platinum weighing 3 ppm of the total weight of the entire structure). And 1-ethynylcyclohexanol serves as a work time conditioning agent (weighing 150 ppm of the total weight of the entire structure). After the foregoing components are evenly mixed, the viscosity of the mixture is 3500 cps at 25° C. Divide the mixture evenly into three portions, respectively (A), (B), and (C).

(A) is used as a blank test;

3 wt % of Magnesium hydroxide (Sigma-Aldrich company U.S.A, reagent grade, 95% purity) is mixed into (B);

5 wt % of the foregoing Magnesium hydroxide is mixed into (C);

Then add 10 wt % of YAG fluorescent powder respectively into (A), (B), and (C). Evenly mix and vacuum de-bubble. Then discharge the mixtures into a mount of a three-chip (0.2 W*3) 5050 SMD LED (8*15 lamp beads per chip) with a capacity measuring digital control dispenser MPP-1 (Musashi Engineering, Inc. Japan). Then place the mount into a hot air circulation drying oven at 80° C. for 1 hour and into a hot air circulation drying oven at 150° C. for 2 hour. Take it out, leave it to cool, and run subsequent reliability test.

### Reliability Result:

(Average result of 8*15 lamp beads per chip, 120 in all)

TABLE 1

| | (A) | (B) | (C) |
|---|---|---|---|
| Original | GOOD | GOOD | GOOD |
| appearance after | | | |
| curing | | | |
| Hardness at 25° C. | 45°D | 47°D | 50°D |
| After | GOOD | GOOD | GOOD |
| high-temperature | | | |
| and high-humidity | | | |
| reflow soldering | | | |
| 200 cycles of | PASS | PASS | PASS |
| temperature | | | |
| cycling | | | |
| Average brightness | 22.0 | 22.2 | 22.5 |
| before sulfidation | | | |
| (Lv) | | | |
| Average brightness | 16.4 | 21.8 | 22.3 |
| after sulfidation | | | |
| (Lv) | | | |
| Brightness decay | 25.4% | 1.8% | 0.9% |
| Average color | 5300-5800 | 5300-5600 | 5300-5600 |
| temperature before | | | |
| sulfidation (K°) | | | |
| Average color | 5800-6400 | 5300-5600 | 5300-5600 |
| temperature after | | | |
| sulfidation (K°) | | | |

Further, (A), (B), and (C) without fluorescent powder are made into transparent bare dies of 20 mm * 50 mm * 1 mm (thickness).

TABLE 2

| | (A) | (B) | (C) |
|---|---|---|---|
| Original light | 85 | 78 | 75 |
| transmittance rate | | | |
| (%) (at 420 nm) | | | |
| Transmission rate | 84 | 78 | 75 |
| after 200° C./72 | | | |
| hours (%) | | | |

### Embodiment 2

Evenly mix polymethylphenylsiloxane polymer containing silica bonded vinyl group with polymethylphenylsiloxane polymer containing silica bonded hydrogen, wherein the content of silica bonded vinyl group is 4.7 wt %, the content of silica bonded hydrogen is 0.14 wt %, and the content of silica bonded phenyl group is 49 wt %. Platinum-1,3-divenyl-1,1,3,3-tetramethyldisiloxane complex serves as a catalyst (weighing 3 ppm of the total weight of the entire structure). And 1-ethynylcyclohexanol serves as a work time conditioning agent (weighing 150 ppm of the total weight of the entire structure). After the foregoing components are evenly mixed, the viscosity of the mixture is 3500 cps at 25° C. Divide the mixture evenly into three portions, respectively (A), (B), and (C).

(A) is used as a blank test;

5 wt % of Magnesium hydroxide (Sigma-Aldrich company U.S.A, reagent grade, specific surface area=130 m²/g, particle size<25 μm (XRD)) is mixed into (B);

5 wt % of talc powder (Sigma-Aldrich company U.S.A, 10 μm) is mixed into (C);

Then add 10 wt % of YAG fluorescent powder (Y959) respectively into (A), (B), and (C). Evenly mix and vacuum de-bubble. Then discharge the mixtures into a mount of a three-chip (0.2 W*3) 5050 SMD LED (8*15 lamp beads per chip) with a capacity measuring digital control dispenser MPP-1 (Musashi Engineering, Inc. Japan). Then place the mount into a hot air circulation drying oven at 80° C. for 1 hour and into a hot air circulation drying oven at 150° C. for 2 hour. Take it out, leave it to cool, and run subsequent reliability test.

### Reliability Result:

(Average result of 8*15 lamp beads per chip, 120 in all)

TABLE 3

| | (A) | (B) | (C) |
|---|---|---|---|
| Original | GOOD | GOOD | GOOD |
| appearance after | | | |
| curing | | | |
| Hardness at 25° C. | 52°D | 56°D | 55°D |
| After | GOOD | GOOD | GOOD |
| high-temperature | | | |
| and high-humidity | | | |
| reflow soldering | | | |
| 200 cycles of | PASS | PASS | PASS |
| temperature | | | |
| cycling | | | |
| Average brightness | 24.2 | 25.2 | 24.0 |
| before sulfidation | | | |
| (Lv) | | | |
| Average brightness | 18.4 | 25.0 | 21.5 |
| after sulfidation | | | |
| (Lv) | | | |
| Brightness decay | 23.9% | 0.8% | 10.0% |
| Average color | 5200-5800 | 5300-5600 | 5300-5600 |
| temperature before | | | |
| sulfidation (K°) | | | |
| Average color | 5700-6400 | 5300-5600 | 5400-5700 |
| temperature after | | | |
| sulfidation (K°) | | | |

Further, (A), (B), and (C) without fluorescent powder are made into transparent bare dies of 20 mm * 50 mm * 1 mm (thickness).

TABLE 4

| | (A) | (B) | (C) |
|---|---|---|---|
| Original light | 85 | 83 | 60 |
| transmittance rate | | | |
| (%) (at 420 nm) | | | |
| Transmission rate | 84 | 83 | 60 |
| after 200° C./72 | | | |
| hours (%) | | | |

The foregoing tables show that the addition of nonorganic magnesium compounds into organopolysiloxane may effectively block the permeation of hydrogen sulfide or sulfide and prevent silver-plated laminates from being oxidated without affecting the average brightness before sulfidation, so that silver-plated laminates may be effectively protected and anti-sulfidation effect may be enhanced. Further, after the addition of nonorganic magnesium compounds, brightness decay is kept under 2%.

1. A curable organopolysiloxane composition, wherein the composition also includes 0.1-50 wt % of nonorganic magnesium compounds, and a particle size of the nonorganic magnesium compounds is greater than 0.1 μm and is less than or equal to 50 μm.

2. A curable organopolysiloxane composition of claim 1, wherein the nonorganic magnesium compounds is one or more from a group including magnesium oxide, magnesium hydroxide, magnesium carbonate, hydrotalcite, hydrotalcite-like compounds, and magnesium silicate.

3. A curable organopolysiloxane composition of claim 1, wherein the content of said nonorganic magnesium compounds is 0.1-20 wt % and the particle size is greater than 0.1 μm and is less than or equal to 20 μm.

4. (canceled)
